(19) United States
(12) Patent Application Publication
(10) Pub. No.: US 2016/0011280 A1
(43) Pub. Date: Jan. 14, 2016

(54) MAGNETIC SENSING APPARATUS, MAGNETIC INDUCTION METHOD AND PREPARATION PROCESS THEREOF

(71) Applicant: QST Corporation [CN/CN], Shanghai (CN)

(72) Inventors: Hong WAN, Shanghai (CN); Xudong WAN, Shanghai (CN); Ting ZHANG, Shanghai (CN)

(73) Assignee: QST Corporation [CN/CN], Shanghai (CN)

(21) Appl. No.: 14/832,788

(22) Filed: Aug. 21, 2015

Related U.S. Application Data
(63) Continuation of application No. PCT/CN2013/088045, filed on Nov. 28, 2013.

(30) Foreign Application Priority Data
Dec. 21, 2012 (CN) 201210563667.3

(51) Int. Cl. G01R 33/02; G01R 33/00; H01L 43/12; G01R 33/09

(52) U.S. Cl. CPC G01R 33/0206; G01R 33/09; G01R 33/0052; H01L 43/12

(57) ABSTRACT

A magnetic sensing apparatus includes a third direction magnetic sensing component. The third direction magnetic sensing component includes: a substrate having groove in its surface; a magnetic conductive unit, and an inducing unit. The main part of the magnetic conductive unit is set in the groove, and a part of it is exposed out the groove and to surface of the substrate, in order to collect magnetic field signal in the third direction and output the magnetic field signal. The inducing unit is disposed on the surface of the substrate, to receive the magnetic field signal in the third direction and measuring corresponding magnetic field strength and direction in the third direction by the magnetic field signal.

### CROSS-REFERENCE TO RELATED APPLICATIONS

This application is a continuation of International Application No. PCT/CN2013/088045 with an international filing date of Nov. 28, 2013, which is based upon and claims priority to Chinese Patent Application No. 201210563667.3, filed Dec. 24, 2012, the entire contents of which are incorporated herein by reference.

### FIELD

The present disclosure belongs to a technical field of electrical communication, refers to a magnetic sensing apparatus, and more particularly to a magnetic three-axis sensing apparatus in a single chip. The present disclosure also refers to a design method to magnetic sense for the magnetic sensing apparatus above. Meanwhile, the present disclosure refers to a preparation technique further on for the magnetic sensing apparatus above.

### BACKGROUND

Magnetic sensor is divided by its principle into hall component, magnetic sensing diode, anisotropic magneto-resistance (AMR) component, tunneling magneto-resistance (TMR) component, giant magneto-resistance (GMR) component, induction coil, and superconductive quantum interference magnetometer.

Electrical compass is one of important application field to magnetic sensor. With rapid development of consumer electronics in recent years, more and more smart phones and panel computers assemble electrical compass beside of navigation system, and it makes users feel very convenience. The magnetic sensor developed from two axis to three axis in recent years. Two-axis magnetic sensor, that is to say plane magnetic sensor, can measure magnetic field strength and direction in a plane illustrated by X and Y-axis.

Operating principle of the magnetic sensor in prior art is shown as below. Anisotropic magneto-resistance material is used in the magnetic sensor to measure the magnetic induction strength in a space. Alloy material with crystal structure adopted here is very sensitive to outside magnetic field, and variation of magnetic field lead to variation of resistance of AMR.

A strong magnetic field is added on an AMR unit to magnetize it in on direction in preparation and application. Then a primary magnetic field is built, and an axis perpendicular to the primary magnetic field is named as sensitive axis of the AMR unit, as illustrated in FIG. 1. Metal wires on the AMR material are canted with 45° to make the measurement result variation linearly, and current flow in these wires and AMR material, as illustrated in FIG. 2. Angle between the primary magnetic field in the AMR material built by the initial strong magnetic field and the current is 45°.

When outside magnetic field Ha exists, direction of the primary magnetic field in AMR unit varies and is not the original direction, and then angel θ between the direction M of magnetic field and current I varies as illustrated in FIG. 3. The variation of θ dues to resistance variation of AMR, as that illustrated in FIG. 4.

The outside magnetic field can be measured by measuring the resistance variation of AMR unit. In real application, a Wheatstone bridge or half Wheatstone bridge in the magnetic sensor is used for measuring the resistance variation of AMR, in order to improve sensitivity of the component, as illustrated in FIG. 5. R1/R2/R3/R4 are ARM resistors with same original state. When outside magnetic field is detected, the resistances of R1/R2 increase ΔR, and these of R3/R4 reduce AR. So the output of bridge is zero when outside magnetic field does not exist; and the output of bridge is a small voltage ΔV when outside magnetic field exists.

A sensing part in a plane (two-axis X, and Y) and a sensing part for Z direction are packaged together in system level to realize triaxial sensing for three-axis sensor in prior art. That is to say, the sensing part in the plane and the sensing part for Z direction are set in two independent wafer or chip, and assembled together by packing. It is impossible to realize triaxial sensing in a single wafer/chip in the prior art.

So, a new magnetic sensing apparatus is needed in the prior art, to product a three-axis sensor in a single wafer/chip.

### SUMMARY

In the present disclosure, in order to solve technical problem, a magnetic sensing apparatus is provided. X-axis, Y-axis, and Z-axis sensing components are set in a single wafer or chip, which is easy to product, has outstanding performance, and has competitive price.

In the present disclosure, a design method to magnetic sense for the magnetic sensing apparatus above is provided. Magnetic data in X-axis, Y-axis, and Z-axis can be induced according the sensing components in the single wafer or chip.

Additionally, a preparation method for the magnetic sensing apparatus is provided, for fabricating the magnetic sensing apparatus assembling X-axis, Y-axis, and Z-axis sensing components in the single wafer or chip.

In a first aspect, a magnetic sensing apparatus includes a third direction magnetic sensing component. The third direction magnetic sensing component includes: a substrate having groove in its surface; a magnetic conductive unit, main part of the magnetic conductive unit is set in the groove, and a part of it is exposed out the groove and to surface of the substrate, in order to collect magnetic field signal in the third direction and output the magnetic field signal; and an inducing unit setting on the surface of the substrate, to receive the magnetic field signal in the third direction and measuring corresponding magnetic field strength and direction in the third direction by the magnetic field signal.

In a second aspect, a magnetic induction method using the magnetic sensing apparatus includes: inducing magnetic field in perpendicular direction, a magnetic conductive unit collects magnetic signal in the perpendicular direction, and outputs the magnetic signal; an inducing unit receives the magnetic signal in the perpendicular direction output by the magnetic conductive unit, and measure the magnetic field strength and magnetic field direction corresponding to the perpendicular direction by the magnetic signal.

In a third aspect, a preparation method for the above magnetic sensing apparatus includes: step S1, provide a substrate; step S2, set grooves in surface of the substrate; step S3, deposit and prepare a magnetic conductive unit, meanwhile deposit an inducing unit on the surface of the substrate, in order to ensure the magnetic conductive unit and the inducing unit are formed by same material deposited in same step; main part of the magnetic conductive unit is deposited in the groove, and a part of it is exposed out the groove to the surface of the substrate; step S4, set an electrical node layer on the inducing unit.

It is to be understood that both the foregoing general description and the following detailed description are exemplary and explanatory only and are not restrictive of the invention.

### DESCRIPTION OF FIGURES

FIG. 1 is schematic diagram for magnetic material of magnetic sensing apparatus in the prior art.

FIG. 2 is schematic diagram for structure of the magnetic material and wire of the magnetic sensing apparatus in the prior art.

FIG. 3 is schematic diagram for angle between magnetic direction and current direction.

FIG. 4 is schematic diagram for θ-R characterization curve of the magnetic material.

FIG. 5 is diagram for a wheatstone bridge.

FIG. 6 is top view diagram for a part of the magnetic sensing apparatus in the present disclosure.

FIG. 7 is section view diagram for the FIG. 1 along AA direction.

FIG. 8 is schematic diagram for structure of the magnetic sensing apparatus in the present disclosure.

FIG. 9 is top view diagram for a part of the magnetic sensing apparatus in second embodiment.

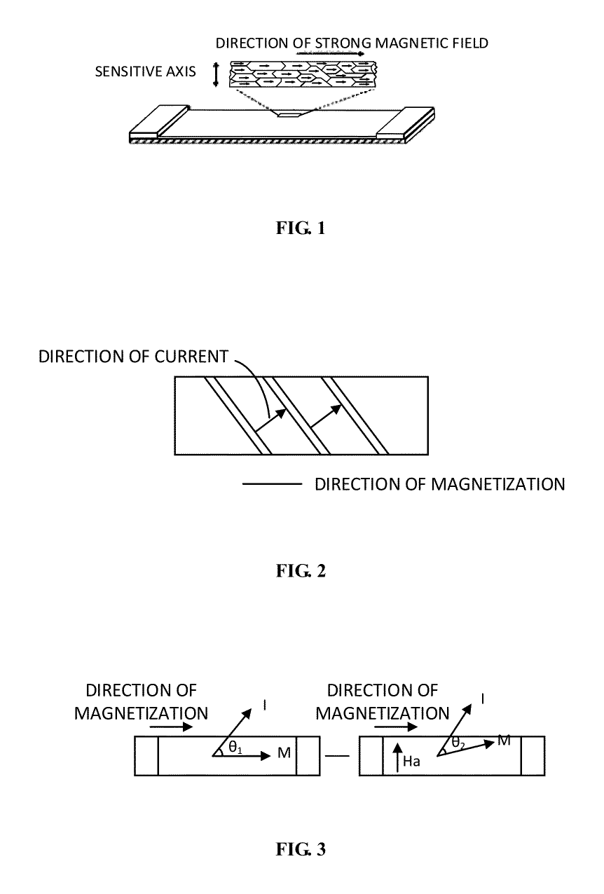

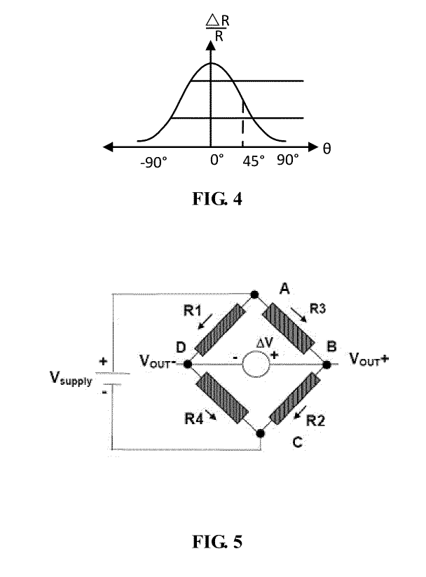

### DETAILED DESCRIPTION

Embodiments of the present disclosure are illustrated as followed with figures.

### First Embodiment

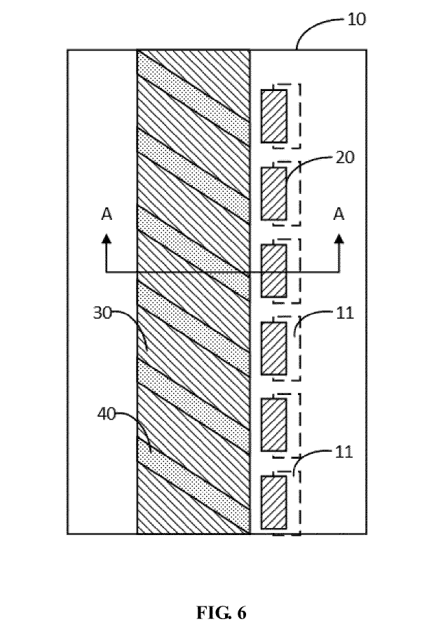

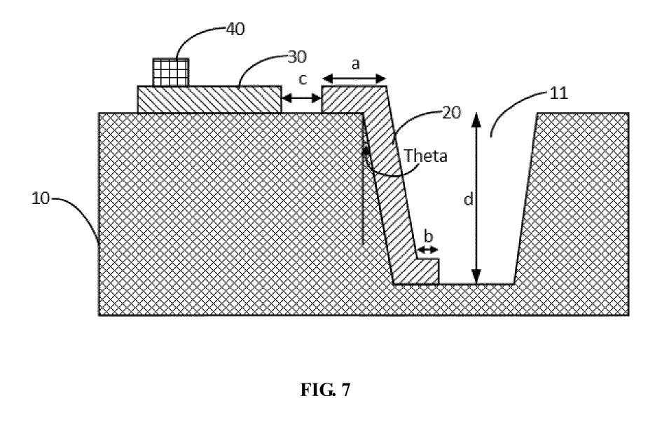

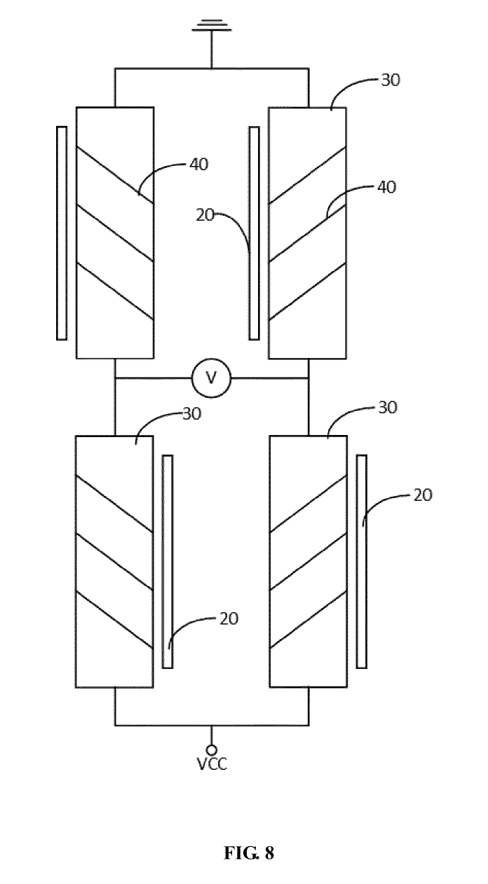

As illustrated in FIG. 6 and FIG. 7, wherein the FIG. 7 is projecting views of FIG. 6 along A-A direction. The present disclosure discloses a magnetic sensing apparatus, which comprises a Z-axis magnetic sensing component. The Z-axis magnetic sensing component comprises: a substrate 10, a magnetic conductive unit 20, and an inducing unit; the substrate 10 may comprise CMOS peripheral circuit.

There is a dielectric layer on surface of the substrate 10, and grooves 11 are in the dielectric layer. One or multiple columns of grooves are set in the substrate. A column of groove comprises multiple sub-grooves 11 in this embodiment.

Main part of the magnetic conductive unit 20 is set in the groove 11, and a part of it is exposed out the groove 11 and to the surface of the substrate, in order to collect magnetic field signal in the Z-axis direction and output the magnetic signal to the inducing unit.

The inducing unit is set on the surface of the substrate, to collect the magnetic field signal in the Z-axis direction output by the magnetic conductive unit 20, and to measure corresponding magnetic field strength and direction in the Z-axis direction by the magnetic field signal. The inducing unit comprises magnetic material layer 30, and multiple parallel nodes 40 are set on the magnetic material layer 30. Meanwhile, the inducing unit is used for sensing magnetic signal in X-axis and Y-axis direction, and measuring the corresponding magnetic field strength and direction in the X-axis and Y-axis direction by the magnetic field signal. The magnetic field in the Z-axis direction is guided to horizontal direction by the inducing unit and then measured, through setting the magnetic conductive unit 20. The magnetic conductive unit 20 and the magnetic material layer 30 of the inducing unit use same magnetic material, have same number of layers, and are deposited in same process; the magnetic conductive unit 20 and the magnetic material layer 30 of the inducing unit can be AMR, TMR and GMR, which is omitted as follows. Of course, the magnetic conductive unit 20 and the magnetic material layer 30 of the inducing unit can also use different magnetic material, or have different number of layers which are fabricated by multiple times of deposition and lithography.

As illustrated in FIG. 7, angle between the main part of the magnetic conductive unit 20 and the plane that comprising the surface of the substrate is 45°˜90°, and larger is better. The magnetic material layer 30 of the inducing unit is directly disposed on the surface of the substrate, and paralleled to the surface of the substrate.

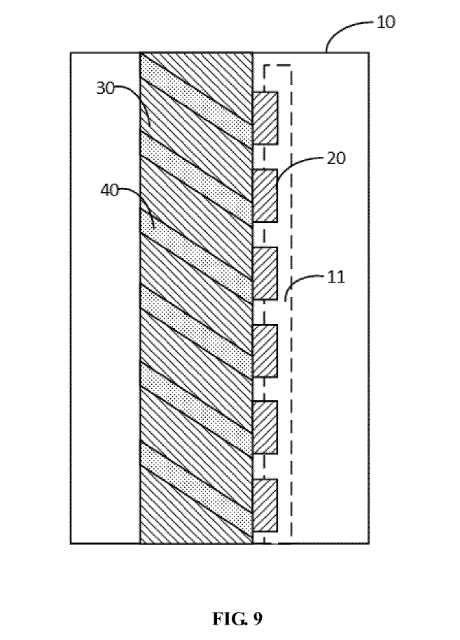

Please refer to FIG. 8, the magnetic conductive unit 20 comprises four magnetic conductive subunits, which are first magnetic conductive subunit, second magnetic conductive subunit, third magnetic conductive subunit, and fourth magnetic conductive subunit. Each magnetic conductive subunit comprises multiple magnetic accessories, main part of the magnetic accessory is set in the corresponding groove 11, and a part of it is exposed out of the groove 11; and the exposed part is directly disposed on the magnetic material layer of the corresponding inducing subunit. Optimized distance c is 0-20 micrometer, and the typical value is 0 micrometer, 0.1 micrometer, 0.3 micrometer, 0.5 micrometer, 0.8 micrometer, 1 micrometer, and 5 micrometer. Meanwhile, as illustrated in FIG. 7, range of a is 0-2 micrometer (such as 0.5 micrometer, 1 micrometer); range of b is 0-1 micrometer (such as 0 micrometer, 0.1 micrometer, and 0.2 micrometer); range of d is 0.5-10 micrometer (such as 3 micrometer, and 2 micrometer); range of angle Theta is 0-45° (such as 5°).

The inducing unit comprises four inducing subunits, which are first inducing subunit, second inducing subunit, third inducing subunit, and fourth inducing subunit. Each inducing subunit comprises magnetic material layer 30, and multiple parallel electrical nodes 40 are set on the magnetic material layer 30; angle between direction setting the electrical node 40 and magnetization direction of magnetic material layer 30 is 10°˜80°, and 45° is optimized.

The first magnetic conductive subunit is coupled with the first inducing subunit as the first inducing module of the magnetic sensing component in the Z-axis; the second magnetic conductive subunit is coupled with the second inducing subunit as the second inducing module of the magnetic sensing component in the Z-axis; the third magnetic conductive subunit is coupled with the third inducing subunit as the third inducing module of the magnetic sensing component in the Z-axis; the fourth magnetic conductive subunit is coupled with the fourth inducing subunit as the fourth inducing module of the magnetic sensing component in the Z-axis.

A Wheatstone bridge is used in the magnetic sensing apparatus as illustrated in FIG. 8, to measure the magnetic field more sensitive. In the field of application, the magnetic field can also be measured by only one magnetic conductive subunit and one inducing substrate, which are omitted here.

In one embodiment of the present disclosure, the apparatus further comprises X-axis Y-axis magnetic sensing component, to induce the magnetic signal in the X-axis or/and Y-axis, and then measure the corresponding magnetic field strength and direction in the X-axis or/and Y-axis direction by it. The X-axis Y-axis magnetic sensing component is not the inducing unit for the Z-axis magnetic sensing component; the inducing unit for the Z-axis magnetic sensing component is for inducing the direction of Z-axis, and the inducing unit for the X-axis Y-axis magnetic sensing component is for inducing the direction of X-axis or/and Y-axis.

The X-axis or Y-axis magnetic sensing component comprises four inducing subunits, which are fifth inducing subunit, sixth inducing subunit, seventh inducing subunit, and eighth inducing subunit; each inducing subunit above comprises a magnetic material layer, on which multiple paralleled electrical nodes are set; and angle between direction of setting the electrical node and direction of magnetization in the magnetic material layer is 10°˜80°, and 45° is optimized. Similarly, the X-axis Y-axis magnetic sensing component can comprise only one inducing unit without Wheatstone bridge.

Structure of the magnetic sensing apparatus in the present disclosure is introduced above, meanwhile a magnetic induction method is disclosed in the present disclosure. The method comprises step of inducing the Z-axis magnetic field, and specifically comprises: a magnetic conductive unit collects magnetic signal in the perpendicular direction, and outputs the magnetic signal; an inducing unit receives the magnetic signal in the perpendicular direction output by the magnetic conductive unit, and measures the magnetic field strength and magnetic field direction corresponding to the perpendicular direction by the magnetic signal.

In addition, the method further comprises the magnetic inducing step in X-axis direction and Y-axis direction, which comprises: induce the magnetic signal in the X-axis direction and Y-axis direction, and measure the magnetic field strength and magnetic field direction corresponding to the X-axis direction and Y-axis direction by the magnetic signal.

Meanwhile, a preparation method for the magnetic sensing apparatus is disclosed in the present disclosure, which comprise the following steps:

[Step S1] provide a substrate, which can comprises CMOS peripheral circuit;

[Step S2] there is a dielectric layer on surface of the substrate, to isolate the sensing apparatus and the substrate, set grooves in surface of the substrate through fabrication method;

[Step S3] deposit the magnetic material and protection layer, which are single layer or multiple layer respectively, and then form the inducing unit and the magnetic conductive unit at the same process through fabrication method, so the magnetic conductive unit and the inducing unit are formed by same material deposited in same step. The main part of the magnetic conductive unit is deposited in the groove, and a part of it is exposed out the groove to the surface of the substrate.

Preferably, the magnetic sensing apparatus in the present disclosure also comprise X-axis Y-axis magnetic sensing component; the magnetic material layer needed by the X-axis Y-axis magnetic sensing component is deposited in the same step the inducing unit and the magnetic conductive unit are deposited in the step S3; that is to say the magnetic material layer need by the X-axis, Y-axis and the inducing unit and the magnetic conductive unit needed by the Z-axis is fabricated in the same step.

Optionally, multiple times of material depositions and fabrication processes are used for forming the inducing unit and the magnetic conductive unit respectively, that is to say different material layers are used for the both.

[Step S4] set the electrical node layer on the inducing unit and the magnetic material layer of the X-axis Y-axis magnetic sensing component, and then finish the fabrication for the whole sensing apparatus through dielectric material depositing, bonding, and so on.

### Second Embodiment

Only difference between the present embodiment and the first embodiment is one groove is shared by multiple magnetic conductive structures in the present disclosure; please refer to FIG. 9, the groove 11 in the substrate 10 can be on or multiple column, and one column of the groove 11 can be set as a long and narrow groove shared by multiple magnetic accessories.

In addition, the magnetic conductive unit can connect to inducing unit in the present structure, that is to say the distance is 0.

### Third Embodiment

In, the present embodiment, the magnetic sensing apparatus in the present disclosure also comprises CMOS chip, and the substrate mentioned in the first embodiment is set on the CMOS chip. It is to say the magnetic sensing apparatus have functions of the CMOS chip in prior art, That is to say functions of the CMOS chip and the sensing apparatus are integrated into a single chip that have high integration.

### Fourth Embodiment

In the present embodiment, the magnetic material layer needed by the magnetic conductive unit of the magnetic sensing apparatus, inducing unit and X-axis Y-axis magnetic sensing component is magnetic resistance material, such as NiFe alloy. Wherein, the magnetic resistance material can be multiple layers material, such as GMR and TMR material, that is to say the magnetic resistance material comprises anisotropic magneto-resistance material, giant magneto-resistance material, or tunneling magneto-resistance material; it can be multiple layer or single layer; and thickness and number of layers of the multiple layer material can be adjusted by needed.

In addition, multiple magnetic conductive structure can be coupled to one group of magnetic conductive unit, to make the measurement more sensitive.

### Fifth Embodiment

In the present embodiment, the three dimensions that the magnetic sensing apparatus can induce may not be the first direction, the second direction, and the perpendicular direction of X-axis, Y-axis and Z-axis. Alternatively or additionally, the magnetic sensing apparatus may induce three-dimensional signals as long as the first direction, the second direction, and the perpendicular direction are perpendicular for any two of them.

Principle of the magnetic sensing apparatus is GMR principle, and the magnetic material is GMR material.

### Sixth Embodiment

In the embodiments above, the magnetic sensor measures and outputs the signal by full Wheatstone bridge. The full Wheatstone bridge comprises four variable arms, that is to say it comprises four magnetic conductive subunits and four inducing subunits, which output the stronger and more effective signal.

Obviously, half bridge, or even quarter bridge, can be used for measuring variation of TMR resistance value (or resistance value of GMR and AMR); two groups of magnetic conductive subunit and two groups of inducing subunit are needed, if using the half bridge for measuring. Only one group of magnetic conductive subunit and one group of inducing subunit are needed, if using the quarter bridge. Here should be specifically mentioned that, just one or two groups of magnetic conductive subunits and inducing subunits can also finish the measurement in the present disclosure, and it is omitted here.

Even not the bridge but only one magnetic conductive unit and one inducing unit are used for measuring the resistance variation of two termination of magnetic unit, to calculate magnetic field variation.

In conclusion, the magnetic sensing apparatus and magnetic induction method thereof are provided in the present disclosure, which can set the sensing devices for X-axis, Y-axis, and Z-axis in one wafer or chip, to have good manufacturability, good performance and obvious competitive price.

The description and application of the present disclosure are illustrative, and does not tend to restrict the present disclosure to the embodiments above. Any transformation and change are allowed for the embodiments, and to replace any embodiment and any components is well known for common skilled persons in the technical field. The skilled persons in the technical field should be clear that, the present disclosure can be in other forms, structure, layout, scale, and other devices, materials and components, within the spirit or essential characteristics of the present disclosure. Any transformation and change are allowed for the embodiments disclosed here, within the scope and spirit of the present disclosure.

Alternatively or additionally, the third direction magnetic sensing component is a perpendicular direction magnetic sensing component; the magnetic conductive unit is used for collecting the magnetic field signal in the perpendicular direction and output the magnetic signal; the inducing unit is a magnetic sensor inducing magnetic field paralleled to the surface of the substrate, sets on the surface of the substrate, and comprises magnetic material layer using for receiving the magnetic field signal in the perpendicular direction output by the magnetic conductive unit, and for measuring corresponding magnetic field strength and direction in the perpendicular direction by the magnetic field signal; the perpendicular direction is perpendicular to the surface of the substrate; and the magnetic sensing apparatus further comprises a first magnetic sensor, and a second magnetic sensor, in order to induce magnetic field in first direction, and second direction respectively. The first direction and the second direction are perpendicular.

Alternatively or additionally, the third direction magnetic sensing component comprises peripheral circuit, to calculate magnetic field strength and direction, and output.

Alternatively or additionally, angle between the main part of the magnetic conductive unit and the surface of the substrate is 45°˜90°; and the inducing unit is directly disposed on the surface of the substrate, and paralleled to the surface of the substrate.

Alternatively or additionally, the inducing unit is a magnetic sensor paralleled to the surface of the substrate, and consists a part of the three dimensions magnetic sensor together with the magnetic sensors corresponding to the first direction and second direction paralleled to the surface of the substrate.

Alternatively or additionally, the inducing units above comprise a magnetic material layer. The magnetic material layer is formed by magnetic resistance material, electrical resistance of which is variable with direction of the magnetic field strength.

Alternatively or additionally, the magnetic conductive unit and the inducing units comprise a magnetic material layer; the magnetic material layer is anisotropic magneto-resistance (AMR) material, giant magneto-resistance (GMR) material, or tunneling magneto-resistance (TMR) material. Principle of the magnetic sensing apparatus is anisotropic magneto-resistance (AMR), giant magneto-resistance (GMR), or tunneling magneto-resistance (TMR).

Alternatively or additionally, the inducing unit can be used for measuring the first direction and/or second direction magnetic field by different arrangement, and the same inducing unit can also be used for measuring the perpendicular direction magnetic field by transferring the perpendicular direction magnetic field to magnetic field corresponding to the first direction or/and second direction; and any two directions in the first direction, the second direction, and the perpendicular direction are perpendicular.

Alternatively or additionally, the inducing unit is a magnetic sensor paralleled to the surface of the substrate, and consists a part of the three dimension magnetic sensor together with the magnetic sensors corresponding to the first direction and second direction paralleled to the surface of the substrate.

Alternatively or additionally, the first direction is X-axis direction, the second direction is Y-axis direction, and the perpendicular direction is Z-axis direction.

Alternatively or additionally, the apparatus further comprises a second magnetic sensing component, to induce the first direction or the second direction magnetic signal, and then measure the magnetic field strength and magnetic field direction corresponding to the first direction or the second direction by it.

Alternatively or additionally, the second magnetic sensing component comprises an inducing subunit at least; each of the inducing subunit above comprises a magnetic material layer. The magnetic material layer is formed by magnetic resistance material, electrical resistance of which is variable with direction of the magnetic field strength.

Alternatively or additionally, the second magnetic sensing component comprises four inducing subunit, which are the fifth inducing subunit, the sixth inducing subunit, the seventh inducing subunit, and the eighth inducing subunit;

each of the inducing subunit above comprises a magnetic material layer, on which multiple paralleled electrical nodes are set; and angle between direction of setting the electrical node and direction of magnetization in the magnetic material layer is 10°˜80°.

Alternatively or additionally, the magnetic conductive unit comprises four magnetic conductive subunits, which are first magnetic conductive subunit, second magnetic conductive subunit, third magnetic conductive subunit, and fourth magnetic conductive subunit; the inducing unit comprises four inducing subunits, which are first inducing subunit, second inducing subunit, third inducing subunit, and fourth inducing subunit; the first magnetic conductive subunit is coupled with the first inducing subunit as the first inducing module of the magnetic sensing component in the perpendicular direction; the second magnetic conductive subunit is coupled with the second inducing subunit as the second inducing module of the magnetic sensing component in the perpendicular direction; the third magnetic conductive subunit is coupled with the third inducing subunit as the third inducing module of the magnetic sensing component in the perpendicular direction; the fourth magnetic conductive subunit is coupled with the fourth inducing subunit as the fourth inducing module of the magnetic sensing component in the perpendicular direction. Each inducing subunit may include a magnetic material layer, on which multiple paralleled electrical nodes are set; angle between direction of setting the electrical node and direction of magnetization in the magnetic material layer is 10°˜80°. One or multiple columns of grooves are set in the substrate, and a column of grooves is formed by a long groove, or a column of grooves comprises multiple sub-grooves.

Each magnetic conductive subunit may include multiple magnetic accessories, main part of the magnetic accessory is set in the corresponding groove, and a part of it is exposed out of the groove; and the exposed part is directly disposed on the magnetic material layer of the corresponding inducing subunit.

Alternatively or additionally, each the magnetic accessory has the exposed part out of the groove, and distance between the exposed part and the magnetic material layer of the corresponding inducing subunit is 0-20 micrometers.

Alternatively or additionally, the magnetic conductive unit and the magnetic material layer of the inducing unit are formed by same magnetic material, and have same number of layers deposited in same step.

Alternatively or additionally, the magnetic conductive unit and the magnetic material layer of the inducing unit are formed by different magnetic material deposited in different steps.

Alternatively or additionally, the method further comprises the inducing step in first direction and second direction. Induce the magnetic signal in the first direction and second direction, and measure the magnetic field strength and magnetic field direction corresponding to the first direction and the second direction by them.

Alternatively or additionally, deposit a magnetic material layer needed by a second magnetic sensing component, meanwhile deposit the inducing unit and the magnetic conductive unit in the step S3. The second magnetic sensing component is used for inducing magnetic sensing signal in first direction and second direction, and measure magnetic field strength and magnetic field direction corresponding to the first direction and the second direction by them; that is to say the magnetic material layer needed by the second magnetic sensing component and the inducing unit, and the magnetic conductive unit needed by the magnetic sensing component in perpendicular direction are formed in the same step.

Alternatively or additionally, the substrate comprises a CMOS circuit in the step S1.

There is a dielectric layer on the surface of the substrate in the step S2, to isolate the sensing apparatus from the substrate, and the grooves are prepared on the dielectric layer;

The magnetic material layer and a barrier layer, which are single layer or multiple layers independently, are deposited on the substrate of the substrate in the step S3, and then the inducing unit and the magnetic conductive layer are formed in the same step, so the inducing unit and the magnetic conductive layer are formed by same magnetic material in the same step, or formed in different steps; and the main part of the magnetic conductive unit is set in the groove, and a part of it is exposed out the groove and to surface of the substrate.

The advantage of the present disclosure is that, a inducing unit with X, Y, and Z-axis direction in a single wafer/chip is provided in the magnetic sensing apparatus and the magnetic induction method provided in the present disclosure, and the peripheral ASIC circuit is integrated optionally on the single chip using fully compatible process with standard CMOS process; and it is easy to product, has outstanding performance, and has competitive price.

What is claimed is:

1. A magnetic sensing apparatus, wherein the apparatus comprises a third direction magnetic sensing component, the third direction magnetic sensing component comprises:
a substrate having a groove in its surface;
a magnetic conductive unit, main part of the magnetic conductive unit is set in the groove, and a part of it is exposed out the groove and to surface of the substrate, in order to collect magnetic field signal in the third direction and output the magnetic field signal; and
an inducing unit disposed on the surface of the substrate, to receive the magnetic field signal in the third direction and measure corresponding magnetic field strength and direction in the third direction by the magnetic field signal.

2. The magnetic sensing apparatus of claim 1, wherein:
the third direction magnetic sensing component is a perpendicular direction magnetic sensing component;
the magnetic conductive unit is configured to collect the magnetic field signal in the perpendicular direction and output the magnetic signal;
the inducing unit is a magnetic sensor inducing magnetic field paralleled to the surface of the substrate, sets on the surface of the substrate, and comprises magnetic material layer configured to receive the magnetic field signal in the perpendicular direction from the magnetic conductive unit, and measure corresponding magnetic field strength and direction in the perpendicular direction by the magnetic field signal; the perpendicular direction is perpendicular to the surface of the substrate; and
the magnetic sensing apparatus further comprises a first magnetic sensor, and a second magnetic sensor configured to respectively induce magnetic field in first direction and second direction, and the first direction and the second direction are perpendicular to each other.

3. The magnetic sensing apparatus of claim 1, wherein:
The third direction magnetic sensing component comprises peripheral circuit, to calculate and output magnetic field strength and direction.

4. The magnetic sensing apparatus of claim 1, wherein:
angle between the main part of the magnetic conductive unit and the surface of the substrate is 45°˜90°; and the inducing unit is directly disposed on the surface of the substrate, and paralleled to the surface of the substrate.

5. The magnetic sensing apparatus of claim 1, wherein:
the inducing unit is a magnetic sensor paralleled to the surface of the substrate, and consists a part of the three dimensions magnetic sensor together with the magnetic sensors corresponding to the first direction and second direction paralleled to the surface of the substrate.

6. The magnetic sensing apparatus of claim 5, wherein:
the first direction is X-axis direction, the second direction is Y-axis direction, and the third direction is Z-axis direction.

7. The magnetic sensing apparatus of claim 1, wherein:
the apparatus further comprises a second magnetic sensing component, to induce the first direction or/and the second direction magnetic signal, and then measure the magnetic field strength and magnetic field direction corresponding to the first direction or/and the second direction by it.

8. The magnetic sensing apparatus of claim 7, wherein:
the second magnetic sensing component comprises an inducing subunit at least;
each of the inducing subunit above comprises a magnetic material layer, and the magnetic material layer is formed by magnetic resistance material, electrical resistance of which is variable with direction of the magnetic field strength.

9. The magnetic sensing apparatus of claim 1, wherein:
the magnetic conductive unit and the inducing units comprise magnetic material layer respectively;
magnetic material of the magnetic material layer is anisotropic magneto-resistance material, giant magneto-resistance material, or tunneling magneto-resistance material; and
principle of the magnetic sensing apparatus is anisotropic magneto-resistance, giant magneto-resistance, or tunneling magneto-resistance.

10. The magnetic sensing apparatus of claim 1, wherein:
the magnetic conductive unit comprises four magnetic conductive subunits, which are first magnetic conductive subunit, second magnetic conductive subunit, third magnetic conductive subunit, and fourth magnetic conductive subunit;
the inducing unit comprises four inducing subunits, which are first inducing subunit, second inducing subunit, third inducing subunit, and fourth inducing subunit;
the first magnetic conductive subunit is coupled with the first inducing subunit as the first inducing module of the magnetic sensing component in the third direction;
the second magnetic conductive subunit is coupled with the second inducing subunit as the second inducing module of the magnetic sensing component in the third direction;
the third magnetic conductive subunit is coupled with the third inducing subunit as the third inducing module of the magnetic sensing component in the third direction;
the fourth magnetic conductive subunit is coupled with the fourth inducing subunit as the fourth inducing module of the magnetic sensing component in the third direction;
each inducing subunit above comprises a magnetic material layer, electrical resistance of which is variable with direction of the magnetic field strength;
one or multiple columns of grooves are set in the substrate, and a column of grooves is formed by a long groove, or a column of grooves comprises multiple sub-grooves; and
each magnetic conductive subunit comprises multiple magnetic accessories, main part of the magnetic accessory is set in the corresponding groove, and a part of it is exposed out of the groove; and the exposed part is directly disposed on the magnetic material layer of the corresponding inducing subunit.

11. The magnetic sensing apparatus of claim 10, wherein:
each the magnetic accessory has the exposed part out of the groove, and distance between the exposed part and the magnetic material layer of the corresponding inducing subunit is 0-20 micrometers.

12. The magnetic sensing apparatus of claim 11, wherein:
the magnetic conductive unit and the magnetic material layer of the inducing unit are formed by same magnetic material, and have same number of layers deposited in same step.

13. The magnetic sensing apparatus described of claim 1, wherein:
the magnetic conductive unit and the magnetic material layer of the inducing unit are formed by different magnetic material deposited in different steps.

14. A magnetic induction method using a magnetic sensing apparatus, comprising:
a magnetic conductive unit collects magnetic signal in the third direction, and outputs the magnetic signal;
an inducing unit receives the magnetic signal in the third direction output by the magnetic conductive unit, and measures the magnetic field strength and magnetic field direction corresponding to the third direction by the magnetic signal,
wherein the apparatus comprises a third direction magnetic sensing component, the third direction magnetic sensing component comprises:
a substrate having a groove in its surface;
a magnetic conductive unit, main part of the magnetic conductive unit is set in the groove, and a part of it is exposed out the groove and to surface of the substrate, in order to collect magnetic field signal in the third direction and output the magnetic field signal; and
an inducing unit setting on the surface of the substrate, to receive the magnetic field signal in the third direction and measuring corresponding magnetic field strength and direction in the third direction by the magnetic field signal.

15. The magnetic induction method of claim 14, wherein:
the method further comprises the inducing step in first direction and second direction, and induce the magnetic signal in the first direction and second direction, and measure the magnetic field strength and magnetic field direction corresponding to the first direction and the second direction by them.

16. A preparation method for a magnetic sensing apparatus, comprising:
step S1, provide a substrate;
step S2, set grooves in surface of the substrate;
step S3, deposit and prepare a magnetic conductive unit, meanwhile deposit an inducing unit on the surface of the substrate, in order to ensure the magnetic conductive unit and the inducing unit are formed by same material deposited in same step; main part of the magnetic conductive unit is deposited in the groove, and a part of it is exposed out the groove to the surface of the substrate;
step S4, set an electrical node layer on the inducing unit.

17. The magnetic induction method of claim 16, wherein:
deposit a magnetic material layer needed by a second and third magnetic sensing component, meanwhile deposit the inducing unit and the magnetic conductive unit in the step S3, and the second and the third magnetic sensing component is used for inducing magnetic sensing signal in first direction and second direction, and measure magnetic field strength and magnetic field direction corresponding to the first direction and the second direction by them; and that is to say the magnetic material layer needed by the second and third magnetic sensing component and the inducing unit, and the magnetic conductive unit needed by the magnetic sensing component in the third direction are formed in the same step.

18. The magnetic induction method of claim 16, wherein:
the substrate comprises a CMOS circuit in the step S1;
there is a dielectric layer on the surface of the substrate in the step S2, to isolate the sensing apparatus from the substrate, and the grooves are prepared on the dielectric layer by fabrication process; and
the magnetic material layer and a barrier layer, which are single layer or multiple layers independently, are deposited on the substrate of the substrate in the step S3, and then the inducing unit and the magnetic conductive layer are formed in the same step, so the inducing unit and the magnetic conductive layer are formed by same magnetic material in the same step; and the main part of the magnetic conductive unit is set in the groove, and a part of it is exposed out the groove and to surface of the substrate; or different magnetic materials formed in different steps.
